(19) United States
(12) Patent Application Publication
(10) Pub. No.: US 2026/0071319 A1
(43) Pub. Date: Mar. 12, 2026

(54) FORMING TOOLS COATED WITH KAPPA-ALUMINA

(71) Applicant: OERLIKON SURFACE SOLUTIONS AG, PFÄFFIKON, PFÄFFIKON (CH)

(72) Inventor: Alfaferi ALFAFERI, BERLIN (DE)

(21) Appl. No.: 18/874,441

(22) PCT Filed: Jun. 15, 2023
(86) PCT No.: PCT/EP2023/066178

§ 371 Date: Dec. 12, 2024

(30) Foreign Application Priority Data
Jun. 15, 2022 (DE) 10 2022 115 112.3

(51) Int. Cl. C23C 16/40; C23C 16/34; C23C 16/36

(52) U.S. Cl. CPC C23C 16/403; C23C 16/34; C23C 16/36

(57) ABSTRACT

A forming tool and a method for producing the same. The forming tool includes a substrate surface to be used as a functional surface. The functional surface is coated with a coating including a kappa-alumina layer as a functional layer.

The present invention relates to a forming tool and a method for producing the inventive forming tool, wherein the inventive forming tool comprises a substrate surface to be used as a functional surface, the functional surface being coated with a coating, wherein the coating comprises a kappa-alumina layer as a functional layer. The kappa-alumina layer being deposited by using a low pressure chemical vapor deposition (LPCVD) process, the forming tool being especially advantageous for aluminum forming processes and aluminum shaping processes, for example in particular (but not limited to) applications in cold forming and shaping processes, i.e. in particular (but not limited to) aluminum cold forming and aluminum shaping processes, wherein in the context of the present invention aluminum forming processes and aluminum shaping processes include as well aluminum alloys forming processes and aluminum alloys shaping processes.

### PRIOR ART

Titanium carbide (TIC) and titanium nitride (TiN) deposited by using chemical vapor deposition (CVD) techniques (hereafter also referred to as CVD-TiC and CVD-TiN are known materials used as coatings for enhancing performance of forming tools applied for cold forming of aluminum. Nevertheless, sticking of aluminum on the forming tool surface is always a drawback and shorten the service life time of the forming tool and the tool must be therefore frequently cleaned.

The use of doped kappa-alumina layers are known for example from the patent application DE 2825009 A1 and the patent specification DE 2825009 C2. In these documents it is described that for the production of monophase or almost monophase kappa-alumina layers having better chip-forming machining performance than other kinds of alumina-containing layers, is necessary to use titanium, zirconium or hafnium as dopant elements, which are provided for the formation of the doped kappa-alumina layer by using titanium tetrachloride, zirconium tetrachloride or hafnium tetrachloride, respectively.

### OBJECTIVE OF THE PRESENT INVENTION

The main objective of the present invention is to provide a new coating solution that overcomes the drawbacks of the currently used coating solutions regarding forming tools applied for cold forming of aluminum.

### DESCRIPTION OF THE PRESENT INVENTION

The objective of the present invention is attained by providing a coated forming tool, which is a forming tool comprising a substrate 1 having a substrate surface to be used as a functional surface, said functional surface being coated with a coating (forming in this manner a coated functional surface), wherein the coating comprises a kappa-alumina layer 20 as a functional layer.

Preferably the coating is applied on the forming tool comprising additionally between said surface of the substrate 1 and said kappa-alumina layer 20 one or more further layers for providing:
enhanced adhesion between the coating and the substrate, in particular to enhance adhesion of the kappa-alumina layer 20 to the substrate surface, and/or
diffusion barrier effect to avoid or reduce diffusion of chemical elements from the substrate 1 (in particular from the substrate surface) to the coating, hence from the substrate surface to the kappa-alumina layer 20, and/or
stress compensation between the substrate 1 and the kappa-alumina layer 20 to obtain enhanced toughness of the coated functional surface, in particular for improving load-bearing capacity of the coated forming tool during application.

According to a preferred embodiment of the present invention, the coating of the inventive forming tool is produced comprising a multilayered film 30 that provides a diffusion barrier effect that makes possible to avoid or at least to reduce diffusion of chemical elements from the substrate surface to the coating, and also provides stress compensation between the surface of the substrate 1 and the kappa-alumina layer 20 for enhancing toughness of the coated functional surface. The multilayered film 30 is preferably deposited comprising TiN layers 32 and TiCN layers 31 deposited alternate one on each other forming a TiN/TiCN/TiN/TiCN . . . architecture.

According to a further preferred embodiment of the present invention, the coating comprises an additional TiN layer deposited as adhesion layer 10 for providing enhanced adhesion of the coating to the substrate surface on which the coating is deposited, and providing at the same time diffusion barrier effect. This adhesion layer is preferably deposited directly on the substrate surface and has preferably a layer thickness in a range from 0.3 μm and 1 μm.

According to one further preferred embodiment of the present invention a further intermediate layer, preferably a TiCN is deposited between the multilayered film 30 and the functional layer 20 of kappa-alumina layer for attaining a clamping effect of the kappa-alumina layer 20 to the multilayered film 30.

Some preferred types of forming tools in the context of the present invention are:
cold forming insert,
form punch,
roll forming tool,
draw and forming insert,
powder compacting tool,
draw ring,
cold forging die,
pierce punch,
cooling core,
die casting forms and core pins,
metal profiling extrusion dies,
metal profiling extrusion tools.

The list of preferred forming tools provided above should be understood only as a list of examples of forming tools in the present invention and not as a limitation of the forming tools that can be considered in the scope of the present invention.

Preferably the kappa-alumina layer is deposited as outermost layer of the coating.

Preferably the kappa-alumina layer is post-treated till attaining a surface quality characterized by an average roughness Ra=0.02 μm, more preferably Ra≤0.02 μm or even Ra<0.02 μm.

Preferably the kappa-alumina layer has a layer thickness in a range from 2 μm to 8 μm, more preferably from 3 μm to 5 μm.

Preferably the total thickness of the coating is in a range from 5 μm to 20 μm, more preferably from 6 μm to 15 μm.

According to the present invention the inventive forming tool is produced by using a method comprising at least following steps:
providing a forming tool comprising a substrate surface to be used as a functional surface,
depositing a coating on the functional surface, wherein during coating deposition at least one kappa-alumina layer is deposited by using low pressure chemical vapor deposition (LPCVD) techniques.

Kappa-alumina produced by using LPCVD has shown to make possible to attain a better wetting behavior of aluminum to the coated surface of the forming tool during forming process in comparison with TiN or TiC coatings, because aluminum does not stick so easy to kappa-alumina as to TiC or TiN.

Hence the present invention makes possible to increase tool performance and service life time of the forming tools used in aluminum processing operation in comparison to the state of the art, because the tools do not need to be cleaned so frequent and the kappa-alumina coating layer is not damaged.

The use of kappa-alumina as coating material instead of TiC has resulted in a significant increment of service life time, of approximately 800%.

The inventive kappa-alumina comprising coating shows better wetting behavior when it interacts with aluminum. This layer has a low Youngs contact angle (of approximately θ<90°) compared to TiN and TiC layer when it interacts with molten aluminum or with an aluminum-alloy.

Comparing the use of TiC as functional coating layer (according to the prior art) with the use of kappa-alumina as functional coating layer (according to the present invention), it was observed that the sticking tendency of aluminum on the tool surface was considerably lower and consequently the tool service life time was longer attaining an increment of approximately 800% before the die needed to be.

This is a very significant breakthrough/advance in the aluminum cold forming (e.g. in aluminum forging applications).

The inventive forming tools according to the present invention are particularly suitable for forming and shaping applications.

According to one preferred embodiment of the present invention, the coating provided on the forming tools is formed comprising following layers:
a TiN layer as adhesion layer and diffusion barrier layer,
a multilayered film comprising TiN and TiCN layers deposited alternate one on each other as stress compensation layer and diffusion barrier layer, and
a kappa-alumina layer (hereafter also referred to as kappa-Al₂O₃ layer) as functional layer, or rather as main functional layer.

### Inventive Example of the Production of a Forming Tool According to the Present Invention

Cold forming tools made of WC-Co having a Co-content in a range between 10 wt. % and 27 wt. % as well as cold forming tools made of steel of the types 1.2343 and steel 1.279, respectively, were coated with according to one example of a preferred embodiment of the present invention by depositing a coating formed by a first coating layer of TiN, a multilayered film consisting of TiN and TiCN coating layers and as outermost layer a kappa-Al₂O₃ coating layer. The coating deposition was conducted as described below:

### 1. Deposition of a TiN Layer:

This TiN layer is deposited as adhesion layer 10 and at the same time provides a diffusion barrier for the elements that could diffuse from the substrate to the coating, which could result in deterioration of coating properties.

The use of a TiN layer as mentioned above is especially recommendable when the substrate is a cemented carbide material, e.g. a WC-Co substrate in which the cobalt content is higher than 8 wt. % (Co>8 wt. %).

In this manner it is possible to avoid that Co diffuses and form Eta-phase at the interface between substrate surface and the coating at high temperatures and low pressure conditions. Beside as diffusion barrier layer, the TiN layer has also the function as adhesion promotor, it means enable good adhesion between the substrate an the further coating layers deposited on the TiN layer.

The TiN layer was deposited according to the reaction below:

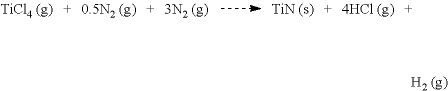

2. Deposition of a multilayered film formed by TiN/TiCN bilayers repeated x-times, where x is preferable in a range between ten and twenty, i.e. the bilayers is preferably repeated between 10 times and 20 times.

This TiN/TiCN multilayered film is provided as interlayer between the first TiN layer deposited as adhesion layer and diffusion barrier layer and the functional layer of kappa-Al₂O₃. This TiN/TiCN multilayered film preferably was deposited consisting of repeated TiN and TiCN layers deposited alternate one on each other forming a TiN/TiCN/TiN/TiCN . . . architecture, which function as a stress compensation interlayer between the first TiN layer and the kappa-Al₂O₃ layer. With this multilayered film stress accumulation can be reduced or interrupted. Furthermore, this multilayered film 30 has also the function of a diffusion barrier.

The TiN- and TiCN-individual layers forming the multilayered film 30 are deposited respectively according to the reactions below:

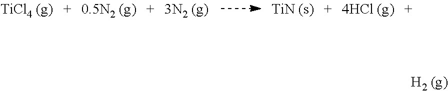

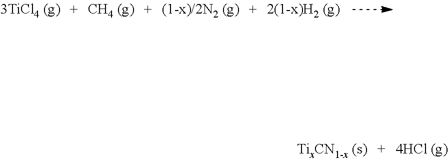

3. Deposition of a Kappa-Al₂O₃ Layer

The kappa-Al₂O₃ is the main functional layer 20. This layer is a hard layer (having hardness preferably in a range between 30 GPa and 35 GPa, more preferably between 33 GPa and 35 GPa), exhibiting chemical and thermal stability at least up to a temperature of 1000° C. Hence, it provides excellent wear resistance at temperatures at least up to 1000° C.

The kappa-Al₂O₃ layer is formed according to the following reactions:
2Al(s)+6HCl(g)+H₂(g)→2AlCl₃(g)+4H₂(g)—in an external aluminum generator at 220-335° C. at 60-100 mbar)
H₂(g)+CO₂(g)→H₂O(g)+CO(g)—insitu in the coating reactor at a temperature of about 1000° C., preferably in a range of 1000° C. to 1050° C., and preferably at a pressure in a range of 65 to 80 mbar.
2AlCl₃(g)+3H₂O(g)+H₂(g)→Al₂O₃(s)+6HCl(g)+H₂(g)—in the coating reactor at a temperature of about 1000° C., preferably in a range of 1000° C. to 1050° C., and preferably at a pressure in a range of 65 to 80 mbar.

The temperature and pressure ranges described above can vary depending on the design of the reactor(s) being used for conducting the LPCVD-processes.

The above described LPCVD process, with respective reactions for producing each one of the above mentioned layers allows the production of coated forming tools, respectively including coated shaping tools having outstanding performance in applications of the type aluminum (including aluminum alloys) forming processes (inclusive very excellent performance in cold forming processes) and shaping processes (inclusive very excellent performance in high-pressure die casting).

The inventors observed that using the reactions and coating parameters as described above allowed following additional benefits:
The kappa-alumina layer (kappa-Al₂O₃ layer) obtained in this manner were produced without any dopants showing in this manner the best combination of properties for attaining outstanding performance in interaction with aluminum and aluminum alloys in forming processes and shaping processes.

The coated cold forming tools were used in aluminum cold forming and a considerably increase in service life time and better oxidation resistance and wear resistance were observed.

In particular in cold forging of aluminum forming tools coated with a CVD-deposited TiC layer as main functional layer (according to the prior art) and forming tools coated with the above mentioned inventive coating (as described in this inventive example) were tested. The CVD-TiC-coated forming tools needed to be cleaned from aluminum sticking on the tool surface after forming of 10 to 50 parts, while the forming tools according to the present example of the present invention needed to be cleaned from aluminum sticking on the tool surface after forming 400 parts. It is an increment in service life time before cleaning of about 800%.

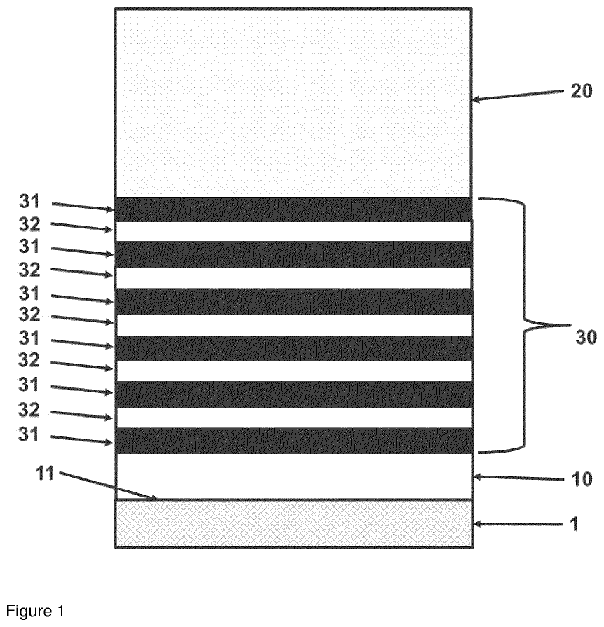

FIG. 1 shows a schematic drawing of a preferred embodiment of a coated part of a coated forming tool, respectively coated shaping tool according to the present invention.

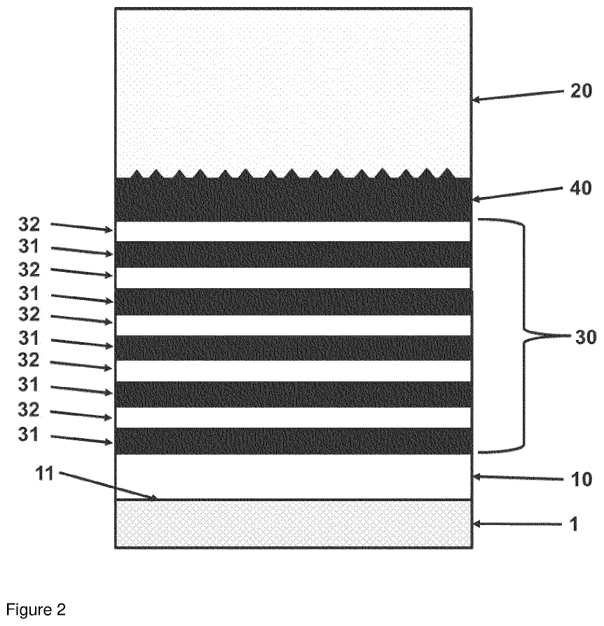

FIG. 2 shows a schematic drawing of a further preferred embodiment of a coated part of a coated forming tool, respectively coated shaping tool according to the present invention, in which a further TiCN layer is deposited between the multilayered coating 30 and the main functional layer 20 for attaining a clamping effect, improving in this manner the bond strength (or cohesive strength) between the kappa-alumina functional layer 20 and the multilayered coating 30.

### CONCRETELY THE PRESENT INVENTION RELATES TO

A forming tool (i.e. in the context of the present invention a forming tool or shaping tool) comprising a substrate surface to be used as a functional surface, the functional surface being coated with a coating, wherein the coating comprises a kappa-alumina layer as a functional layer, which does not comprise dopant elements.

The forming tool, whose coating preferably comprising between the substrate surface and the kappa-alumina layer one or more further layers providing:
enhanced adhesion between the coating and the substrate surface, and/or
diffusion barrier effect for avoiding or reducing diffusion of chemical elements from the substrate surface to the coating, and/or
stress compensation between the substrate surface and the kappa-alumina layer for enhancing toughness of the coated functional surface, in particular for improving load-bearing capacity.

The forming tool, whose coating preferably comprising a multilayered film comprising TiN layers 32 and TiCN layers 31 deposited alternate one on each forming a TiN/TiCN/TiN/TiCN . . . architecture providing diffusion barrier effect for avoiding or reducing diffusion of chemical elements from the substrate surface to the coating, and also providing stress compensation between the substrate surface and the kappa-alumina layer for enhancing toughness of the coated functional surface.

The forming tool, whose coating preferably comprising a TiN layer providing enhanced adhesion between the coating and the substrate surface and diffusion barrier effect.

The forming tool is preferably a forming tool or shaping tool of at least one of following types of tools:
cold forming insert,
form punch,
roll forming tool,
draw and forming insert,
powder compacting tool,
draw ring,
cold forging die,
pierce punch,
cooling core,
die casting forms and core pins,
metal profiling extrusion dies,
metal profiling extrusion tools.

The forming tool, whose kappa-alumina layer is preferably deposited as outermost layer of the coating.

The forming tool, whose kappa-alumina layer preferably has a surface quality characterized by an average roughness Ra=0.02 μm, more preferably Ra≤0.02 μm or even Ra<0.02 μm.

The forming tool, whose kappa-alumina layer preferably has a layer thickness in a range from 2 μm to 8 μm, preferably from 3 μm to 5 μm.

The forming tool, preferably having total thickness of the coating is in a range from 5 μm to 20 μm, preferably from 6 μm to 15 μm.

The forming tool, wherein preferably between the multilayered film 30 and the kappa-alumina layer 20 a further layer 40 having a clamping function is deposited for improving bond strength between the multilayered film 30 and the kappa-alumina layer 20. This layer 40 being preferably a TiCN layer deposited by using the same reaction described above for the deposition of the TiCN layers 31, however having a greater thickness, selected in such a manner that the mentioned clamping function is attained.

A method for producing a forming tool according to any of the previous embodiments as mentioned above or combinations thereof, the method comprising following steps:
providing a forming tool comprising a substrate surface to be used as a functional surface,
depositing a coating on the functional surface, wherein during coating deposition at least one kappa-alumina layer without any dopant elements is deposited by using low pressure chemical vapor deposition techniques.

The method, in which preferably the kappa-alumina layer is formed by using following reactions, the temperature and pressure selected depending on the reactor used for deposition:

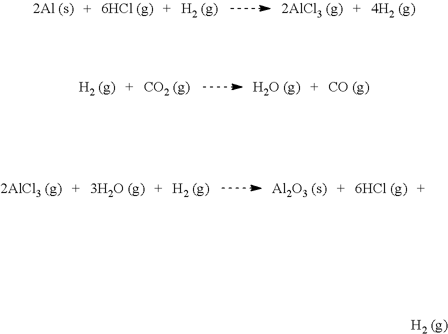

1.-12. (canceled)

13. A forming tool comprising a substrate with a substrate surface to be used as a functional surface, the substrate surface being coated with a coating, wherein the coating comprises a kappa-alumina layer as a functional layer, wherein the kappa alumina layer does not comprise dopant elements.

14. The forming tool according to claim 13, wherein the coating further comprises, between the substrate surface and the kappa-alumina layer, one or more further layers comprising at least TiN or TiCN, providing:
enhanced adhesion between the coating and the substrate surface,
a diffusion barrier effect for avoiding or reducing diffusion of chemical elements from the substrate surface to the coating, or
stress compensation between the substrate surface and the kappa-alumina layer for enhancing toughness of the coated substrate surface.

15. The forming tool according to claim 14, wherein the coating further comprises a multilayered film comprising TiN layers and TiCN layers alternately deposited on each other forming a TiN/TiCN/TiN/TiCN . . . architecture providing the diffusion barrier effect for avoiding or reducing diffusion of chemical elements from the substrate surface to the coating, and also providing the stress compensation between the substrate surface and the kappa-alumina layer for enhancing the toughness of the coated substrate surface.

16. The forming tool according to claim 14, wherein the coating further comprises an adhesion layer, which is a TiN layer providing the enhanced adhesion between the coating and the substrate surface and the diffusion barrier effect.

17. The forming tool according to claim 16, wherein the adhesion layer is deposited directly on the substrate surface and has a layer thickness in a range from 0.3 μm to 1 μm.

18. The forming tool according to claim 15, wherein an intermediate layer is deposited between the multilayered film and the kappa-alumina layer for attaining a clamping effect of the kappa-alumina layer to the multilayered film.

19. The forming tool according to claim 18, wherein the intermediate layer is a TiCN layer.

20. The forming tool according to claim 13, wherein the forming tool is selected from the group consisting of at least one of: a cold forming insert, a form punch, a roll forming tool, a draw and forming insert, a powder compacting tool, a draw ring, a cold forging die, a pierce punch, a cooling core, a die casting forms and core pins, metal profiling extrusion dies, and metal profiling extrusion tools.

21. The forming tool according to claim 13, wherein the kappa-alumina layer is an outermost layer of the coating.

22. The forming tool according to claim 13, wherein the kappa-alumina layer has a surface quality having an average roughness Ra≤0.02 μm.

23. The forming tool according to claim 13, wherein the kappa-alumina layer has a layer thickness in a range from 2 μm to 8 μm.

24. The forming tool according to claim 13, wherein a total thickness of the coating is in a range from 5 μm to 20 μm.

25. The forming tool according to claim 13, comprising, between the multilayered film and the kappa-alumina layer a further layer having a clamping function for improving bond strength between the multilayered film and the kappa-alumina layer.

26. A method for producing the forming tool according to claim 13, comprising:
providing a forming tool comprising a substrate surface to be used as a functional surface,
depositing a coating on the substrate surface, wherein during coating deposition at least one kappa-alumina layer without any dopant elements is deposited by using low pressure chemical vapor deposition techniques.

27. The method according to claim 26, wherein the kappa-alumina layer is formed by using the following reactions, temperature and pressure being selected depending on a reactor used for deposition: [chemical structure]
